(19) United States
(12) Patent Application Publication
(10) Pub. No.: US 2026/0221187 A1
(43) Pub. Date: Jul. 30, 2026

(54) ARRAY STABILIZATION IN MEMORY ARCHITECTURES

(71) Applicant: Micron Technology, Inc., Boise, ID (US)

(72) Inventors: Darwin A. Clampitt, Wilder, ID (US); Steven P. Turini, Boise, ID (US); Kevin Y. Titus, Meridian, ID (US)

(21) Appl. No.: 19/427,822

(22) Filed: Dec. 19, 2025

Related U.S. Application Data
(60) Provisional application No. 63/751,203, filed on Jan. 29, 2025.

(51) Int. Cl. G11C 16/04

(52) U.S. Cl. CPC G11C 16/0483

(57) ABSTRACT

Methods, systems, and devices for array stabilization in memory architectures are described. A memory device may include a first array region with a first block of memory cells and a first selection region. The memory device may include a second array region of the memory die with a second block of memory cells and a second selection region. The first and second selection regions may include respective sets of transistors that couple memory cells of the first block and the second block with various access lines. The memory device may include an electrical isolation region positioned between the first array region and the second array region. The electrical isolation region may include first dielectric material portions having a first width between the first selection region and the second selection region and second dielectric material portions having a second width between the first selection region and the second selection region.

### CROSS REFERENCE

The present Application for Patent claims priority to U.S. Patent Application No. 63/751,203 by Clampitt et al., entitled “ARRAY STABILIZATION IN MEMORY ARCHITECTURES,” filed January 29, 2025, which is assigned to the assignee hereof, and which is expressly incorporated by reference in its entirety herein.

### TECHNICAL FIELD

The following relates to one or more systems for memory, including memory devices and methods for forming memory devices that include array stabilization in memory architectures.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory system, including at least a portion of a memory device, that supports array stabilization in memory architectures in accordance with examples as disclosed herein.

FIG. 2 shows an example of a memory architecture that may be implemented in a memory device that supports array stabilization in memory architectures in accordance with examples as disclosed herein.

FIG. 3 shows an example of a portion of a device that supports array stabilization in memory architectures in accordance with examples as disclosed herein.

FIGS. 4 through 11 illustrate examples of fabrication operations that support formation of a device including array stabilization in memory architectures in accordance with examples as disclosed herein.

FIG. 12 shows a flowchart illustrating a method or methods of forming at least a portion of a memory device that includes array stabilization in memory architectures in accordance with examples as disclosed herein.

### DETAILED DESCRIPTION

Some electronic devices, including memory devices (e.g., memory systems, memory dies, memory chips, processing systems, or other semiconductor devices), may utilize three-dimensional (3D) memory structures (e.g., 3D not-AND (NAND) memory architectures, or other 3D memory architectures) that include stacks of material layers. During fabrication of such devices, one or more voids (e.g., slits, cavities, trenches, holes) may be formed through portions of the material layers by etching, cutting, or otherwise removing portions of the stacked materials. In some cases, such voids may support formation of circuit components such as vias, conductive lines (e.g., access lines, word lines, or traces), memory cell materials, isolation regions (e.g., regions that electrically isolate one portion of the device from another), or other components. However, material removal to form voids may reduce mechanical support of material layers and may result in bending and misalignment due to various stresses (e.g., mechanical stress, thermal stress, material strain) that occur during fabrication. Such bending may lead to inconsistent positioning of device materials, thus degrading device performance (e.g., of memory operations), decreasing device yield (e.g., due to fabrication errors, due to implementing relatively larger component spacing to accommodate relatively larger positioning tolerances), or both. Moreover, some techniques to compensate for block bending may increase manufacturing complexity, cost, or both as a result of associated processing steps.

In accordance with one or more techniques described herein, an electronic device (e.g., a memory device, a 3D NAND device, a semiconductor device) may be fabricated with operations that improve structural stability of the device along with reduced impact to manufacturing complexity. For example, one or more sacrificial materials may be formed during one or more intermediate operations, providing mechanical stability for subsequent operations. In some examples, operations to support forming such sacrificial materials may be performed concurrently with other fabrication operations (e.g., the formation of semiconductor channels). The sacrificial materials may support formation of an electrical isolation region between array regions of the memory device. As described herein, an “array region” may refer to a region of a memory device that includes at least a first portion associated with a block of memory cells and a second portion associated with a selection region (e.g., a select gate drain (SGD) region), where the selection region may include circuitry (e.g., transistor circuitry) operable to couple the memory cells of the block with one or more access lines (e.g., enabling the reading and writing of data to the memory cells). An “electrical isolation region” may refer to a region within a device that electrically separates different portions of the device to prevent unwanted electrical interaction between them.

An electrical isolation region may be formed based on various formation operations (e.g., material removal, material deposition). For example, a first set of voids (e.g., slits, cavities, holes) may be formed through a portion of selection regions and through the one or more sacrificial materials. The first voids may be spaced apart such that one or more continuous portions of material (e.g., selection region material, bridges of material) remain between the array regions to stabilize the structure during subsequent processes (e.g., during a replacement gate (RG) process), and may be filled with a first dielectric material. In some examples, the first voids may be formed concurrently with one or more other cavities associated with forming strings of memory cells. To support forming an electrical isolation between the array regions, one or more second voids may be formed between the first voids (e.g., filled voids), and the second voids may be filled with a second dielectric material. In some examples, the second voids may be differentiated from the first voids based on having different widths, being filled with different materials, or having a material boundary (e.g., a visible discontinuity, a grain boundary) between the filled voids. Thus, utilizing such techniques may enhance the mechanical stability of the memory structure during manufacturing, which may reduce block bending effects and component misalignment. As such, memory devices may be fabricated with relatively lower cost, higher yield, and improved device performance and reliability, among other benefits.

In addition to applicability in memory systems as described herein, techniques for array stabilization in memory architectures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by supporting relatively higher density memory devices, which may improve performance of data intensive applications and decrease processing or latency times, among other benefits.

Features of the disclosure are illustrated and described in the context of systems, devices, and circuits. Features of the disclosure are further illustrated and described in the context of devices, operations, and flowcharts.

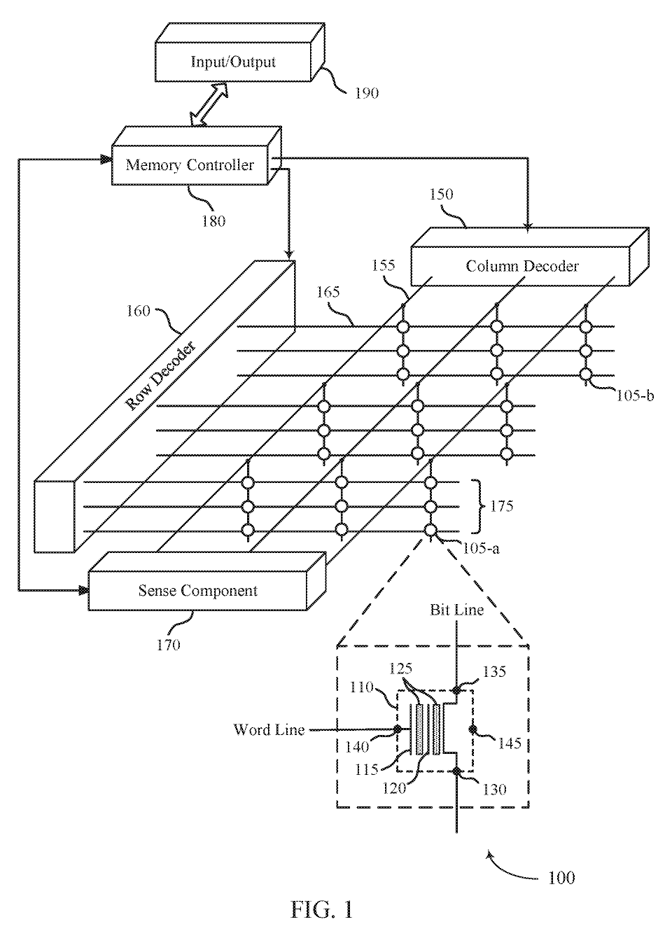

FIG. 1 shows an example of a memory system 100, including at least a portion of a memory device, that supports array stabilization in memory architectures in accordance with examples as disclosed herein. FIG. 1 is an illustrative representation of various components and features of the memory system 100. As such, the components and features of the memory system 100 are shown to illustrate functional interrelationships, and not necessarily physical positions within the memory system 100. Further, although some elements included in FIG. 1 are labeled with a numeric indicator, some other corresponding elements are not labeled, even though they are the same or would be understood to be similar, in an effort to increase visibility and clarity of the depicted features.

The memory system 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

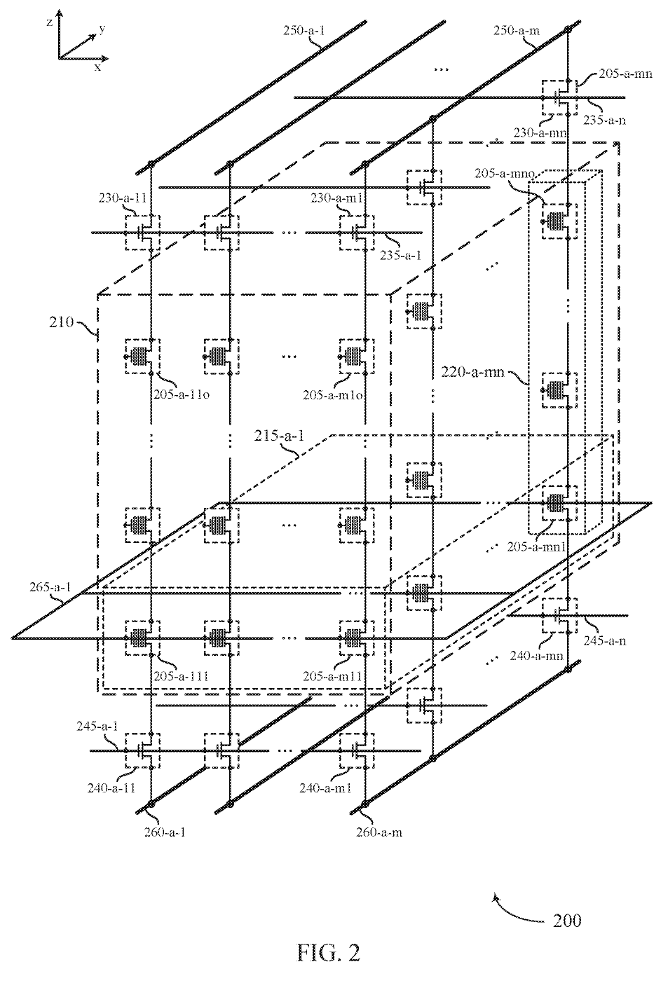

In some cases, a memory system 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory system 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory system 100.

A memory system 100 may utilize a 3D structure formed of various material layers (e.g., associated with memory cell stack 175 and other components). During fabrication, one or more voids may be formed through portions of the memory system 100 to support formation of other components (e.g., word lines 165, bit lines 155, or portions of a memory cell 105), which may result in bending and misalignment due to various stresses (e.g., mechanical stress, thermal stress, material strain). Such bending may lead to inconsistent positioning of device materials, thus degrading device performance (e.g., of the memory cells 105), decreasing device yield, or both. In accordance with techniques herein, a memory system 100 may be fabricated using various operations that improve structural stability. For example, one or more sacrificial materials may be formed during one or more intermediate operations, providing mechanical stability for subsequent operations. The sacrificial materials may further support formation of an electrical isolation region between different array regions of the memory system 100, which may be formed based on various sets of voids (e.g., slits, cavities, holes, trenches) formed at respective operations. Thus, utilizing such techniques may enhance the mechanical stability of the memory system 100 (e.g., during manufacturing), which may reduce block bending and misalignment effects. As such, the memory system 100 may be fabricated to support improved performance, increased reliability, and increased capacity, among other benefits.

FIG. 2 shows an example of a memory architecture 200 that may be implemented in a memory device that supports array stabilization in memory architectures in accordance with examples as disclosed herein. The memory architecture 200 may be an example of a portion of a memory system, such as a memory system 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory system 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m x n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget > VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget < VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

In some cases, during fabrication of a memory device in accordance with the memory architecture 200, one or more voids may be formed through a stack of material layers to support formation of components of the memory architecture 200 (e.g., strings 220, select lines 235, bit lines 250, word lines 265, or a portion of memory cells 205), which may result in bending and misalignment due to various stresses (e.g., mechanical and thermal stress). This bending may lead to inconsistent placement of device materials, which may degrade performance of the memory architecture 200, decrease yield, or both. To mitigate such effects, the one or more techniques herein enable a memory architecture 200 to be fabricated using operations that support improved structural stability. For example, one or more sacrificial materials may be formed during one or more intermediate fabrication operations, which may increase mechanical stability for subsequent operations.

In some examples, the sacrificial materials may support formation of an electrical isolation region between array regions of the memory architecture 200. An array region may be associated with a block 210 and a corresponding selection region (e.g., including transistors 230 and select lines 235, or transistors 240 and select lines 245, or both that are associated with the block 210 of the array region). Circuitry of the selection region (e.g., transistors 230, transistors 240) may be operable to couple memory cells 205 of the array region with access lines (e.g., bit lines 250, source lines 260). An electrical isolation region may electrically isolate one array region from another, and may be formed based on various formations of voids (e.g., slits, cavities, holes, trenches) between blocks 210. The voids may be supported by one or more continuous portions of material (e.g., selection region material, bridges of material) that remain between the array regions (e.g., between a first selection region of a first array region and a second selection region of a second array region), which may stabilize the structure. In some examples, the voids may be formed concurrently with one or more other cavities associated with accessing strings 220. Thus, utilizing such techniques may enhance the mechanical stability of the memory architecture 200 (e.g., during manufacturing), which may reduce block bending and misalignment effects. As such, a memory architecture 200 may support improved performance, increased reliability, and increased capacity, and provide other benefits for a memory system.

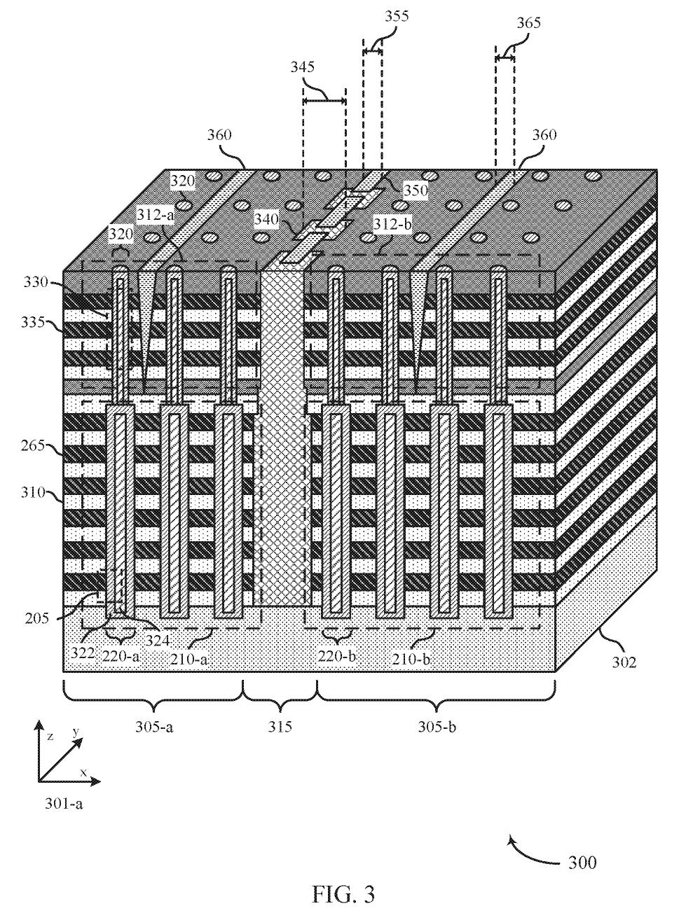

FIG. 3 shows an example of a portion of device 300 that supports array stabilization in memory architectures in accordance with examples as disclosed herein. The device 300 (e.g., a memory die, a memory device, a NAND device, a 3D NAND device, a memory system, a NAND system, an electronic device) may be an example of or include at least a portion of a memory system 100, or a memory architecture 200 or another implementation of a semiconductor component (e.g., a memory component, a processing component). The device 300 may be described with reference to an x-direction, a y-direction, and a z-direction of the illustrated coordinate system 301-a. For example, the device 300 may be illustrated in accordance with a cut plane (e.g., illustrating a cross-sectional view of the xz-plane) as well as a top view (e.g., along the z-direction). Although the device 300 may illustrate example quantities of components, a device 300 may support alternative implementations that include more or fewer components than shown, as well as alternative configurations.

The device 300 may include multiple array regions 305 (e.g., each including a respective selection region 312 and a block 210) and isolation regions 315 (e.g., electrical isolation regions) between array regions 305. In some examples, the device 300 may be formed over a substrate 302, which may include a semiconductor substrate with which circuitry (e.g., transistors, circuitry of a column decoder 150, circuitry of a row decoder 160, circuitry of a sense component 170, circuitry of a memory controller 180) may be formed, or may be a non-functional (e.g., sacrificial) substrate.

In the illustrated example, the device 300 includes an array region 305-a and an array region 305-b. The array region 305-a includes a block 210-a and a selection region 312-a over the block 210-a, and the array region 305-b includes a block 210-b and a selection region 312-b over the block 210-b. The selection regions 312 may include respective sets of transistors (e.g., transistors 110, transistors 230, transistors 240), and each transistor may be located at a respective portion 330 where one or more activation lines 335 (e.g., a select line 235, a select line 245, formed of a conductive material) couple with a portion of a channel 320 (e.g., a semiconductor channel, a string or pillar associated with the selection region 312-a). Transistors of a selection region 312 may be operable to couple memory cells 205 of a corresponding block 210 with one or more access lines (not shown). For example, each transistor of the selection region 312-a may be operable to couple a respective string 220-a of the block 210-a with a respective first access line (e.g., above the block 210-a) and each transistor of the selection region 312-b may be operable to couple a respective string 220-b of the block 210-b with a respective second access line (e.g., above the block 210-b). In some examples, the access lines may include bit lines 155, bit lines 250, source lines 260, or other lines (e.g., conductive traces, buses) used for accessing (e.g., programming, writing data to, reading data from) the memory cells 205. In some examples, the first transistors may be operable to couple the memory cells 205 with an access line based on one or more activation lines 335 (e.g., based on an activation voltage applied to the activation line 335).

In some examples, each of the strings 220 (e.g., of the block 210-a and the block 210-b) may include a respective semiconductor channel 322 (e.g., a semiconductor material portion of the string 220, a polysilicon material) along the string 220. Each string may further include a dielectric material 324 (e.g., a dielectric core of the channel) and a storage material (e.g., of a charge trapping structure 120, not shown), where the storage material may be formed continuously along the semiconductor channel 322, or may be formed in discontinuous portions (e.g., between layers of material 310, with respective word lines 265). In some examples, each semiconductor channel 322 may include a set of multiple channel portions each associated with a respective memory cell 205 along the string 220. The array region 305-a and the array region 305-b may include respective word lines 265 (e.g., formed of conductive material) associated with the block 210-a or with the block 210-b, which may be associated with accessing respective memory cells 205 along the strings 220. In some examples, the device 300 may include multiple layers of a material 310 (e.g., an oxide material, a dielectric material), which may isolate the word lines 265 from each other, may isolate the activation lines 335 from each other, or both. In some examples, each channel portion of a string 220 may be coupled with a respective portion of a storage material (e.g., a charge trapping structure 120) of the associated memory cell 205. In some implementations, each of the transistors of the selection regions 312 may not include the storage material (e.g., may be formed as de-integrated SGDs, referring to being de-integrated from the strings 220).

In the illustrated example, the device 300 includes an isolation region 315 positioned between the array region 305-a and the array region 305-b. The isolation region 315 may include various dielectric materials that electrically isolate circuitry of the array region 305-a from circuitry of the array region 305-b, and vice versa. For example, the isolation region 315 may include one or more portions 340 of a first dielectric material having a width 345 between the selection region 312-a and the selection region 312-b. The isolation region 315 may further include one or more portions 350 of a second dielectric material having a width 355 between the selection region 312-a and the selection region 312-b. In some examples, the width 345 of the portions 340 may be wider than the width 355 of the portions 350.

In some examples, the isolation region 315 may include the first dielectric material positioned between the block 210-a and the block 210-b (e.g., at a first depth in the device 300). In some examples, the second dielectric material may be a same dielectric material as the first dielectric material or a different dielectric material. In some examples, the portions 340 may be formed at a first depth (e.g., along the z-direction) through the device 300 (e.g., through a depth of the selection regions 312 and the blocks 210) and the portions 350 may be formed a second depth through the device 300 (e.g., as deep as or deeper than selection regions 312, not as deep or not through a depth of blocks 210). For example, the first depth may be different than (e.g., deeper than) the second depth. In some examples, the portions 340 and the portions 350 may be distinguishable by one or more discontinuities (e.g., a visible discontinuity, a material boundary, a formation boundary) between the portions 340 and the portions 350 (e.g., including cases in which both portions include the same dielectric material) or by differing dielectric materials. Although the portions 340 and the portions 350 are shown with example dimensions and shapes, such portions may be formed using different dimensions and shapes than shown.

In some examples, word lines 265 of the array region 305-a may be isolated from word lines 265 of the array region 305-b based on the first dielectric material of the isolation region 315 positioned between the block 210-a and the block 210-b. That is, the first dielectric material of the isolation region 315 may be continuous along a direction (e.g., the y-direction) between the blocks 210. The first dielectric material may not be continuous between the selection regions 312. That is, activation lines 335 of the selection region 312-a may be isolated from the activation lines 335 of the selection region 312-b based on both the first dielectric material and the second dielectric material of the isolation region 315. In some examples, the device 300 may include one or more additional isolation regions 360 (e.g., electrical isolation regions) through the selection region 312-a or the selection region 312-b, or both. The isolation regions 360 may have a width 365 (e.g., different than or the same as the width 345 or the width 355) and may include a same dielectric material as the portions 350 or the portions 340 (e.g., the second dielectric material of the portions 350). In such examples, the isolation regions 360 may separate subsets of activation lines 335 (e.g., associated with sub-blocks of a respective block 210) of the selection region 312-a, of the selection region 312-b, or both based on the dielectric material.

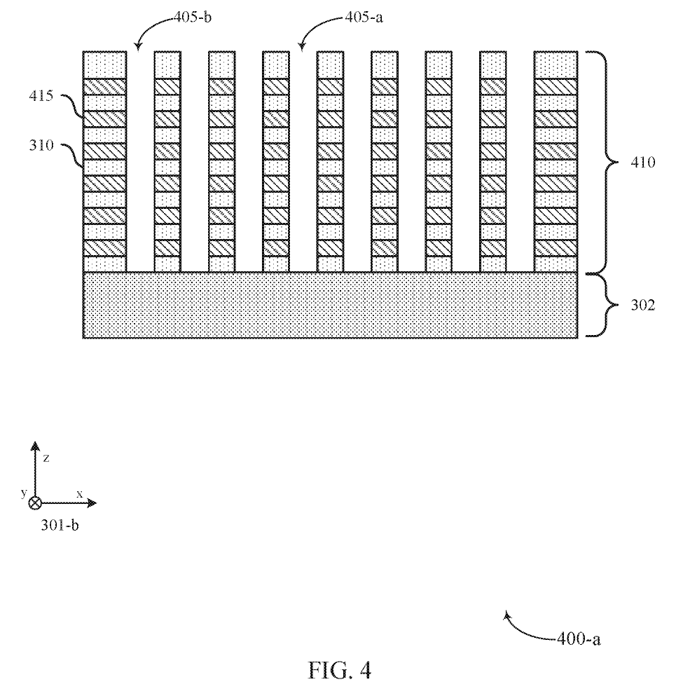

FIGS. 4 through 11 show examples of fabrication operations that support formation of a device including array stabilization in memory architectures in accordance with examples as disclosed herein. For example, FIGS. 4 through 12 may illustrate a sequence of operations for fabricating aspects of a device 400 (e.g., a device 300, a memory device, a NAND device, a 3D NAND device, a memory system, a NAND system, an electronic device), which may be an example of, or include a portion of, a memory system 100, or a memory architecture 200 or another implementation of a semiconductor component (e.g., a memory component, a processing component). In some examples, the device 400 may be a memory die, such as a NAND die (e.g., a 3D-NAND die, a die having an arrangement of NAND memory cells arranged in a 3D array).

Each of FIGS. 4 through 12 may illustrate aspects of the device 400 after different subsets of the fabrication operations for forming the device 400 (e.g., illustrated as a device 400-a after a first set of one or more fabrication operations, as a device 400-b after a second set of one or more fabrication operations, and so on). Each view of FIGS. 4 through 12 may be described with reference to an x-direction, a y-direction, and a z-direction of the illustrated coordinate systems 301-b. For example, aspects of the device 400 may be illustrated in accordance with a cut plane (e.g., along an xz-plane) to show embedded features of the device 400, or may be illustrated in accordance with the cut plane and a top view (e.g., a diagonal view, illustrating a cross-sectional view of the xz-plane as well as at a least a portion along the y plane) to show other features of the device 400.

Operations illustrated in and described with reference to FIGS. 4 through 12 may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the device 400. In some examples, operations performed by such a manufacturing system may be supported by a process controller or its components as described herein (e.g., including instructions stored in a non-transitory computer-readable medium that are executable by a processing system to cause the manufacturing system to perform the operations).

Although aspects of the device 400 illustrate examples of relative dimensions and quantities of various features, aspects of the device 400 may be implemented with other relative dimensions or quantities of such features in accordance with examples as disclosed herein. Moreover, aspects of the device 400 may be repeated in various manners (e.g., along the x-direction, along the y-direction, along the z-direction). In the following description of the device 400, some methods, techniques, processes, and operations may be performed in different orders, or at different times, or otherwise modified. Further, some operations for fabricating a device 400 may be omitted from the described fabrication operations, or other operations may be added to the described fabrication operations.

In some examples, portions of the device 400 that are illustrated with a same fill pattern may be formed of same or similar materials and portions that are illustrated with different patterns may be formed of different materials. Various material layers are described herein, which may include an aluminum nitride, a silicon carbide, a silicon oxide, a silicon nitride, a silicon carbon nitride, a tetraethyl orthosilicate (TEOS), a boron arsenide, some other dielectric material such as some other oxide or nitride material, or any combination thereof. Additionally, conductive materials described herein may include copper, aluminum, tungsten, titanium, some other conductive material, or any combination thereof.

FIG. 4 shows an example of a cross-sectional view of a device 400-a after a first set of one or more fabrication operations. For example, the first operations may include forming a set of cavities 405 through a stack 410 (e.g., of material layers) associated with one or more blocks (e.g., a block 210-a and a block 210-b) of memory cells (e.g., memory cells 205). In some examples, forming the cavities may include forming one or more cavities 405-a (e.g., bridge pillar slots), which may be used for a sacrificial material, and one or more cavities 405-b (e.g., cylindrical cavities), which may be used for forming strings 220. In some examples, forming the cavities 405 may include one or more patterning and etching operations. In some examples, the stack 410 may include alternating layers of a material 310 (e.g., an oxide material, a dielectric material) and a material 415 (e.g., a nitride material, a sacrificial material). In some examples, the stack 410 may be formed over a substrate 302 (e.g., a semiconductor substrate, a substrate material).

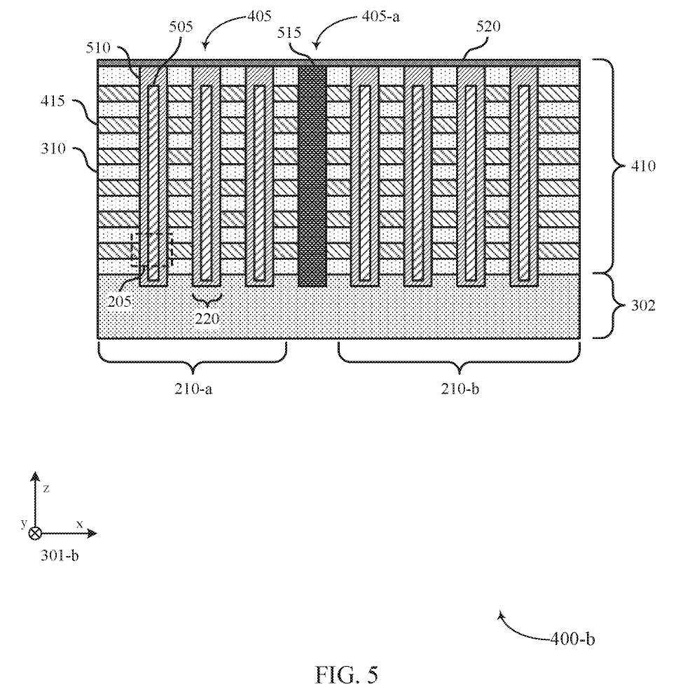

FIG. 5 shows an example of a cross-sectional view of a device 400-b after a second set of one or more fabrication operations. For example, the second operations may include forming a block 210-a and a block 210-b over the substrate 302. In some examples, the second operations may include forming a sacrificial material 515 (e.g., a carbon material, a polysilicon material) in a cavity 405-a (e.g., a bridge pillar, in at least one cavity 405) and covering the device 400 with a material 520 (e.g., an oxide material, a dielectric material). In some examples, the second operations may include (e.g., after forming the sacrificial material 515 and covering with material 520) forming a set strings 220 (e.g., semiconductor channels, NAND channels, pillars), which may be based on forming a material 505 (e.g., a dielectric material 324), a material 510 (e.g., a semiconductor material, associated with a respective semiconductor channel 322), and a storage material (not shown, continuously along the material 510 along the z-direction or discontinuously between layers of the material 310, which may be associated with charge trapping structures 120) in one or more cavities 405. In some examples, the second operations may include forming one or more conductive pads (e.g., SGD landing pads) over the string 220 and covering the device 400 with material 520 (e.g., which may be different than the material 310).

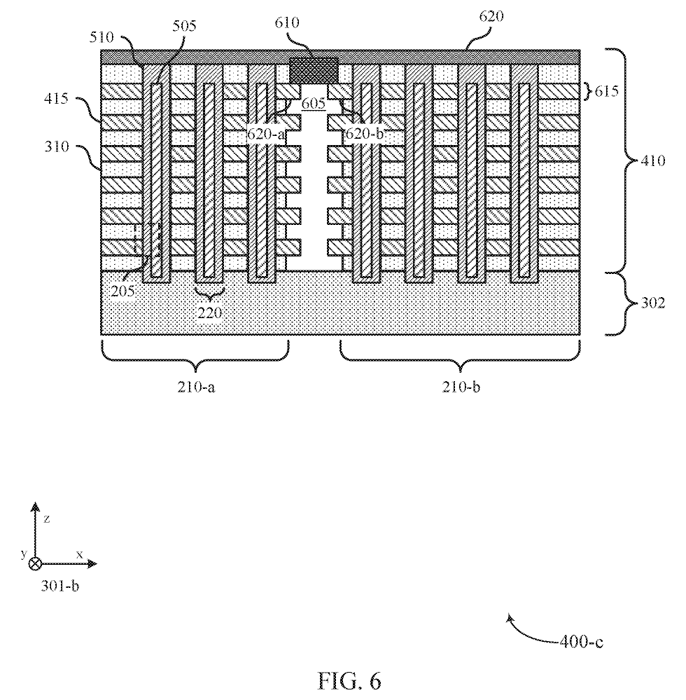

FIG. 6 shows an example of a cross-sectional view of a device 400-c after a third set of one or more fabrication operations. For example, the third operations may include forming a void 605 (e.g., a cavity, a trench) between the block 210-a and the block 210-b. In some examples, forming the void 605 may be based on removing the sacrificial material 515 from the cavity 405-a. In some examples, forming an electrical isolation region may be based on forming the void 605. In some examples, forming the void 605 may include patterning and etching operations to access the sacrificial material 515, exhuming the sacrificial material 515, and etching (e.g., recessing) a portion of the material 310 within the void 605 (e.g., and the material 310 may no longer include continuous portions that span between the block 210-a and the block 210-b).

The third operations may also include forming a material 610 (e.g., a sacrificial material, a carbon material, a polysilicon material) over the void 605 and over a top layer 615 of the stack 410 (e.g., of the material 415) on opposite sides (e.g., a side 620-a and a side 620-b) of the void 605 (e.g., by filling the tops of the void 605 with the material 610 and removing any excess material from the surface of the device 400-c). At this stage, in some examples, the structure of the device 400-c may be supported by the material 610 and continuous portions of the material 415 (e.g., a nitride mesh, portions of nitride across the void 605 that were not etched during the formation of the cavities 405, which may be located into our out of the illustrated xz-plane along the y-direction). In some examples, the formation of the material 610 may improve structural integrity of the device 400 (e.g., during subsequent manufacturing operations) and may reduce block bending effects. The third operations may further include covering the device 400-c with a material 620 (e.g., an oxide material, a dielectric material, which may be different from the material 310).

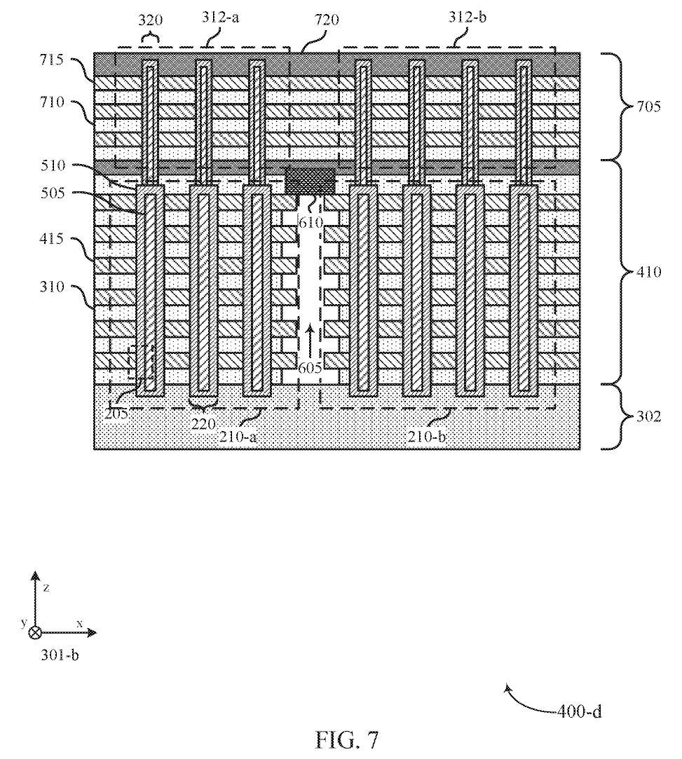

FIG. 7 shows an example of a cross-sectional view of a device 400-d after a fourth set of one or more fabrication operations. For example, the fourth operations may include forming selection regions 312 (e.g., SGD regions, depositing SGD tiers) over the stack 410. The material 610 may provide additional mechanical support to the structure of the device 400-d, which may reduce block bending effects that may occur based on the formation of the selection regions 312. The selection region 312 may include a stack 705 (e.g., of material layers), including alternating layers of a material 710 (e.g., an oxide material, a dielectric material) and a material 715 (e.g., a nitride material, a sacrificial material) which may be the same materials or different materials than the material 310 and the material 415, respectively. In some examples, the selection regions 312 may include a selection region 312-a (e.g., a first selection region) over the block 210-a and a selection region 312-b (e.g., a second selection region) over the block 210-b (e.g., the different selection regions 312 may not be isolated at this stage).

In some examples, forming the selection regions 312 may include forming one or more channels 320 (e.g., based on forming one or more cavities and forming a semiconductor material and dielectric material core in the one or more cavities), which may extend to respective strings 220. Alternatively, the one or more channels 320 may not be formed at this stage (e.g., and may be formed during a later fabrication operation, the channels 320 may be absent from the device 400-d). In some examples, the selection region 312-a and the selection region 312-b may be associated with respective sets of transistors (e.g., transistors of respective portions 330) operable to couple memory cells 205 of the block 210-a and memory cells 205 the block 210-b with one or more respective access lines (e.g., formed above the selection regions 312, bit lines 155, bit lines 250, source lines 260, not shown). In some examples, the fourth operations may include covering the device 400-d with a material 720 (e.g., an oxide material, a dielectric material, which may be different than the material 310).

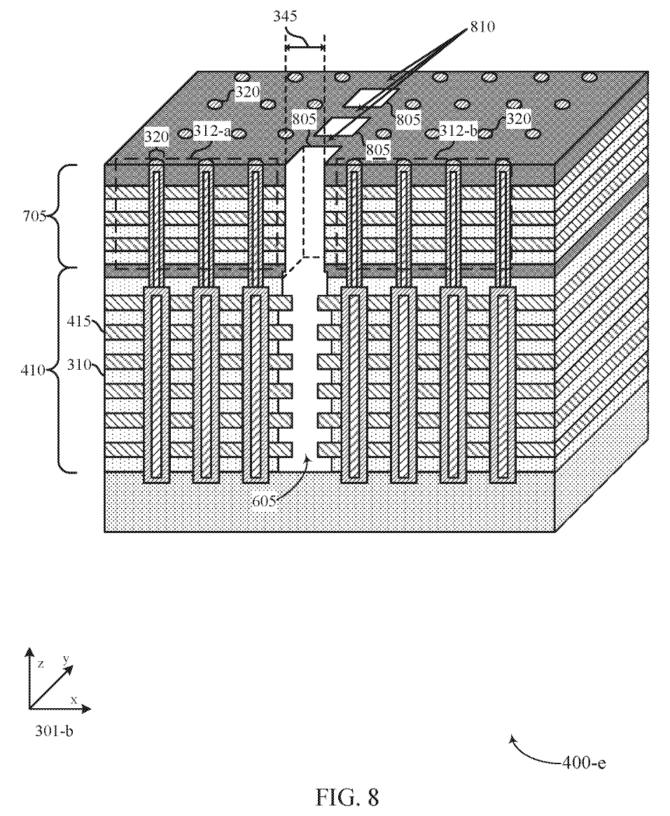

FIG. 8 shows an example of a 3D view of a device 400-e after a fifth set of one or more fabrication operations. For example, the fifth operations may include forming one or more cavities 805 (e.g., access holes, slits, voids) through the stack 705 (e.g., between the selection regions 312-a and 312-b. In some examples, the cavities 805 may have a width 345 and may extend to the material 610 formed over the void 605. For example, the cavities 805 may be formed (e.g., etched) down to a top surface of the material 610. Subsequently, the material 610 may be removed (e.g., exhumed) based on forming the cavities 805. In some examples, the stack 705 may include one or more continuous portions 810 of material (e.g., material bridges, support structure) from the selection region 312-a to the selection region 312-b (e.g., extending between the selection regions 312, along the x-direction). For example, the continuous portions 810 may be formed between the cavities 805 (e.g., along the y-direction). That is, the continuous portions 810 (e.g., of material 710 and material 715) may remain intact along the stack 705 after the formation of the cavities 805 (e.g., based on a spacing between the cavities 805). Thus, at this stage, the structure of the device 400-e may be supported based on the continuous portions 810 (e.g., and a mesh of materials 415 in the region of the stack 410, where applicable). In some other examples, the one or more channels 320 of the selection regions 312 may not be formed at this stage (e.g., and may be formed during a later fabrication operation, the channels 320 may be absent from the device 400-e).

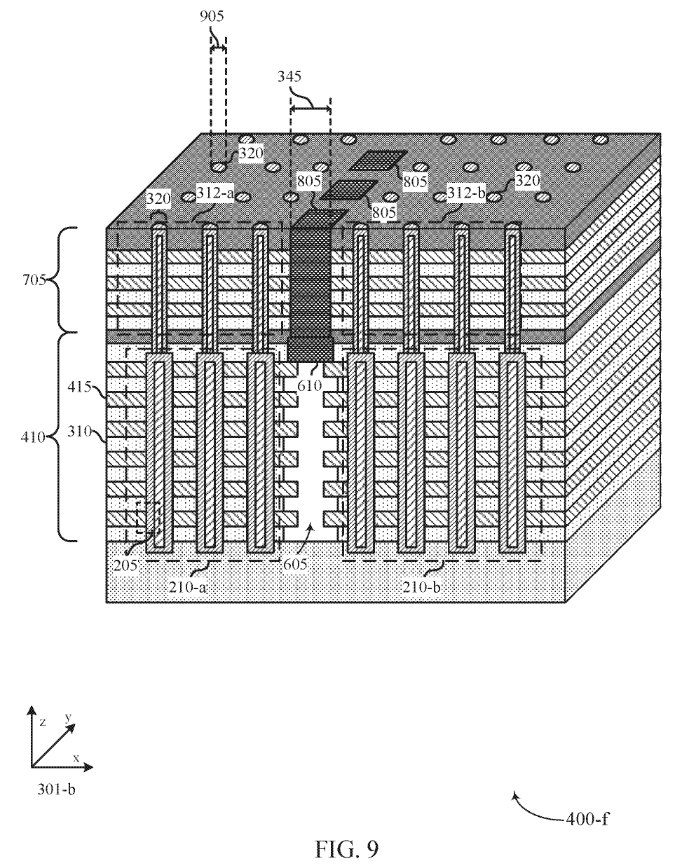

FIG. 9 shows an example of a 3D view of a device 400-f after a sixth set of one or more fabrication operations. In some examples, the sixth operations may illustrate one or more alternative (e.g., optional) implementations. That is, the sixth operations may be performed additionally, alternatively, or not at all with respect to other techniques described herein (e.g., with reference to the fabrication operations described in FIGS. 4 through 11). In some examples, the sixth operations may include concurrently forming the one or more cavities 805 (e.g., voids) between the selection region 312-a and the selection region 312-b and forming one or more cavities for the one or more channels 320 (e.g., prior to filling the channels 320 with semiconductor material and dielectric material) through the selection region 312-a and the selection region 312-b. For example, the cavities 805 may have the width 345 and may extend to the material 610 formed over the void 605 between the block 210-a and the block 210-b. In some examples, the cavities formed for the channels 320 may have a width 905 and may extend to respective strings 220 associated with the block 210-a and the block 210-b.

In some examples, after forming the cavities 805 and the cavities for the channels 320, a material (e.g., a sacrificial material) may be formed in the cavities 805 and the device 400-f may be covered with another material (e.g., an oxide material, a dielectric material). Subsequently, portions of the other material over the cavities for the channels 320 may be removed, and semiconductor material and dielectric material may be formed in the cavities, which may form the channels 320. That is, transistors of the selection regions 312 may be operable based on the semiconductor material (e.g., and the dielectric core material, where applicable). The sixth operations may further include covering the device 400-f with another material (e.g., an oxide material, a dielectric material).

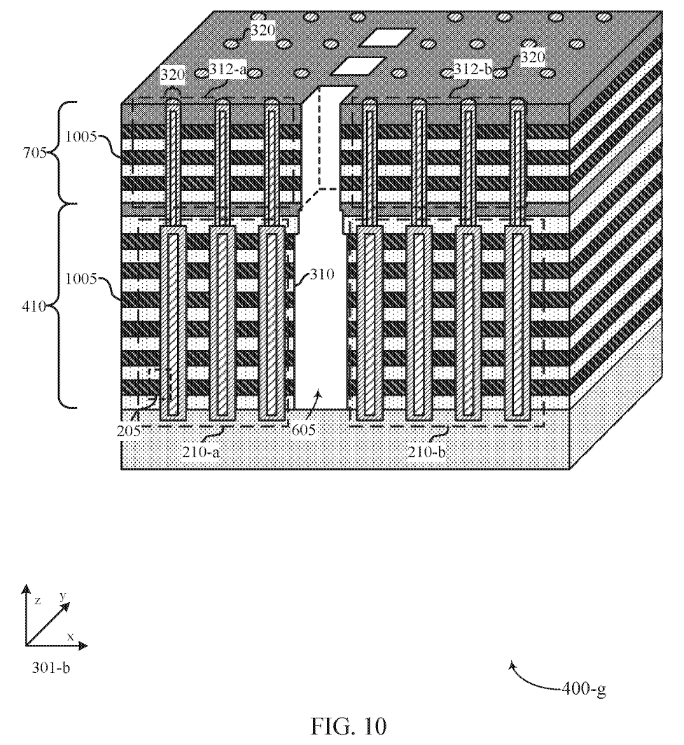

FIG. 10 shows an example of a 3D view of a device 400-g after a seventh set of one or more fabrication operations. For example, the seventh operations may include replacing (e.g., prior to forming an electrical isolation region, exhuming) one or more layers of a material (e.g., a nitride material, material 415, material 715) of the block 210-a, the block 210-b, the selection region 312-a, and the selection region 312-b with material 1005 (e.g., one or more conductive materials). Such operations may be referred to, in some examples, as an RG process. In some examples, transistors (e.g., memory cells 205) of the blocks 210 and the selection regions 312 may be operable based on replacing the material(s) with the material 1005 (e.g., the conductive materials may form a transistor gate that is operable to control the semiconductor portions along the channels 320 and the strings 220). In some examples, the seventh operations may include removing (e.g., etching) at least a portion of the materials 310 (e.g., within the void 605, the material 1005 and the material 310 may be substantially coplanar within the void 605).

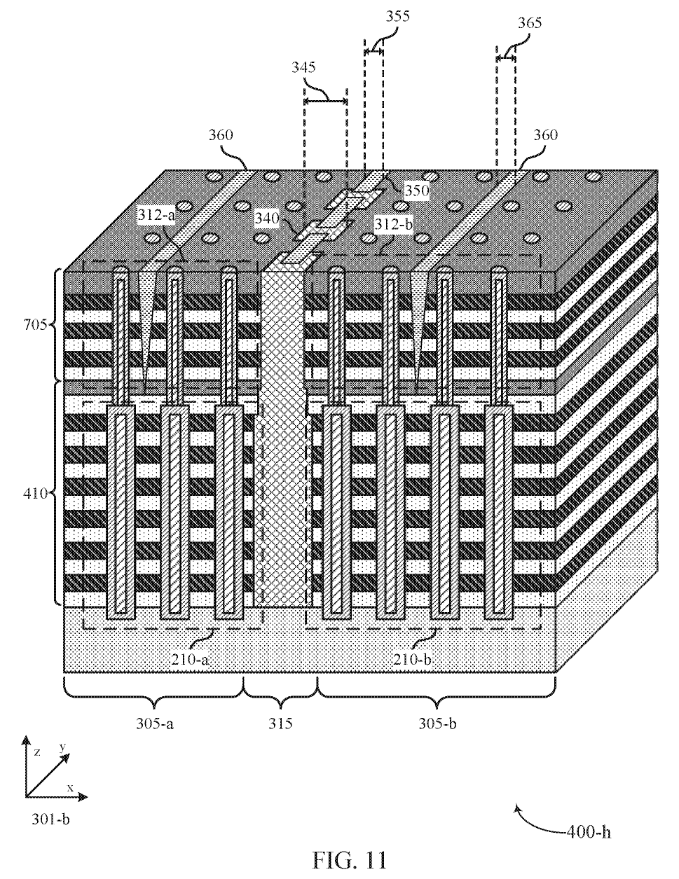

FIG. 11 shows an example of a 3D view of a device 400-h after an eighth set of one or more fabrication operations. For example, the eighth operations may include forming an isolation region 315 between the selection region 312-a and the selection region 312-b. In some examples, the isolation region 315 may include one or more portions 340 of a first dielectric material, which may have the width 345 between the selection region 312-a and the selection region 312-b. In some examples, the isolation region 315 may include one or more portions 350 of a second dielectric material, which may have a width 355 (e.g., narrower than the width 345) between the selection region 312-a and the selection region 312-b. In some examples, forming the portions 340 of the first dielectric material may be based on forming the first dielectric material in one or more cavities (e.g., void 605, cavities 805).

In some examples, the eighth operations may include forming the portions 350 by forming one or more voids having the width 355. Each of the one or more voids may extend between the first portions 340 of the first dielectric material, and the second dielectric material may be formed in the one or more voids. Although a non-limiting example of multiple portions 350 being formed, a single continuous portion 350 may be formed (e.g., along the y-direction). In some examples, the portions 350 may be formed after forming the first dielectric material of the portions 340. For example, one or more cavities may be formed through the first dielectric materials (e.g., and through portions of the stack 705 of material layers) of the portions 340 and may be filled with the second dielectric material thus forming the portions 350.

In some examples, the eighth operations may include forming one or more isolation regions 360 (e.g., concurrently with forming the portions 350) through the selection region 312-a, the selection region 312-b, or both. In some examples, the one or more isolation regions 360 may include (e.g., be filled with) the second dielectric material (e.g., after filling cavities or trenches for the isolation region 360 with the second dielectric material). In some examples, forming the isolation region 315 may isolate the block 210-a from the block 210-b (e.g., forming SGD sub-blocks). Additionally, or alternatively, forming the isolation regions 360 may isolate each selection region 312 into two or more sub-regions (e.g., may segment the SGD in slit segments, may segment activation lines 235).

Accordingly, by applying one or more fabrications operations described herein, devices 400 may be fabricated with increased yield based on enhanced mechanical stability during manufacture. For example, by forming a material 610 (e.g., prior to SGD formation), continuous portions 810, and other features, the device 400 may be more resistant to block bending effects, which may mitigate component misalignment. As such, devices 400 may be fabricated with reduced cost, increased yield, and improved device performance and reliability, among other benefits.

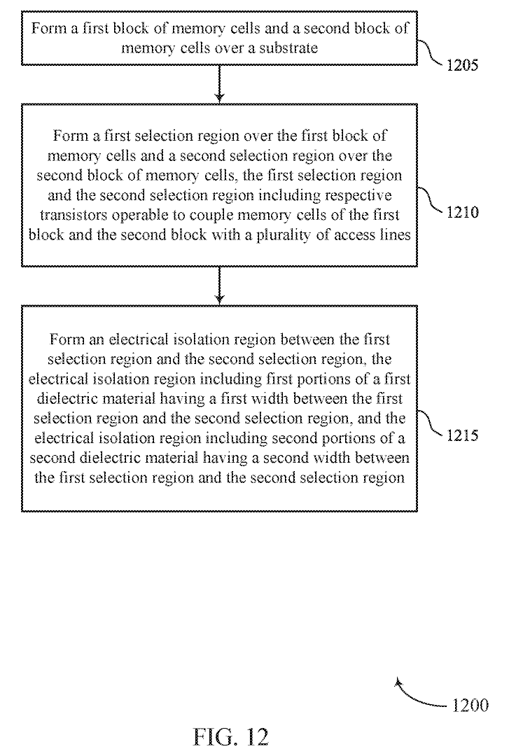

FIG. 12 shows a flowchart illustrating a method or methods 1200 that support forming at least a portion of a memory device that includes array stabilization in memory architectures in accordance with examples as disclosed herein. The operations of method 1200 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1205, the method may include forming a first block of memory cells (e.g., a first block 210) and a second block of memory cells (e.g., a second block 210) over a substrate (e.g., a substrate 302).

At 1210, the method may include forming a first selection region (e.g., a selection region 312) over the first block of memory cells and a second selection region (e.g., a selection region 312) over the second block of memory cells, the first selection region and the second selection region including respective transistors (e.g., transistors 230, transistors 240) operable to couple memory cells of the first block and the second block with a plurality of access lines (e.g., access lines 250, access lines 260).

At 1215, the method may include forming an electrical isolation region (e.g., an isolation region 315) between the first selection region and the second selection region, the electrical isolation region including first portions (e.g., portions 340) of a first dielectric material having a first width between the first selection region and the second selection region, and the electrical isolation region including second portions (e.g., portions 350) of a second dielectric material having a second width between the first selection region and the second selection region (e.g., the second width being different than the first width).

In some examples, an apparatus (e.g., a manufacturing system) as described herein may perform a method or methods, such as the method 1200. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a first block of memory cells and a second block of memory cells over a substrate; forming a first selection region over the first block of memory cells and a second selection region over the second block of memory cells, the first selection region and the second selection region including respective transistors operable to couple memory cells of the first block and the second block with a plurality of access lines; and forming an electrical isolation region between the first selection region and the second selection region, the electrical isolation region including first portions of a first dielectric material having a first width between the first selection region and the second selection region, and the electrical isolation region including second portions of a second dielectric material having a second width between the first selection region and the second selection region (e.g., the second width being different than the first width).

Aspect 2: The method or apparatus of aspect 1, where forming the first block of memory cells and the second block of memory cells includes operations, features, circuitry, logic, means, or instructions, or any combination thereof for forming, prior to forming the first selection region and the second selection region, a plurality of cavities through a stack of material layers associated with the first block of memory cells and the second block of memory cells, the stack of material layers including alternating layers of an oxide material and a nitride material and forming a plurality of strings of memory cells based at least in part on forming a semiconductor material and a storage material in a plurality of first cavities of the plurality of cavities.

Aspect 3: The method or apparatus of aspect 2, further including operations, features, circuitry, logic, means, or instructions, or any combination thereof for forming a void between the first block of memory cells and the second block of memory cells based at least in part on removing a first sacrificial material from one or more second cavities of the plurality of cavities, where forming the electrical isolation region is based at least in part on forming the void and forming a second sacrificial material over the void and over a top layer of the stack of material layers on opposite sides of the void.

Aspect 4: The method or apparatus of any of aspects 1 through 3, further including operations, features, circuitry, logic, means, or instructions, or any combination thereof for forming a plurality of first cavities through a stack of material layers of the first selection region and the second selection region, the stack of material layers including alternating layers of an oxide material and a nitride material, the plurality of first cavities having the first width and extending to a sacrificial material formed over a second void between the first block of memory cells and the second block of memory cells, and the stack of material layers including continuous portions from the first selection region to the second selection region between the plurality of first cavities, and forming the first portions of the first dielectric material based at least in part on forming the first dielectric material in the plurality of first cavities.

Aspect 5: The method or apparatus of any of aspects 1 through 4, further including operations, features, circuitry, logic, means, or instructions, or any combination thereof for replacing, prior to forming the electrical isolation region, a plurality of layers of a nitride material of the first block of memory cells, the second block of memory cells, the first selection region, and the second selection region with a conductive material (e.g., while one or more oxide layers extend from the first selection region to the second selection region over one or more voids between the first block of memory cells and the second block of memory cells), where the respective transistors are operable based at least in part on replacing the nitride material with the conductive material.

Aspect 6: The method or apparatus of any of aspects 1 through 5, further including operations, features, circuitry, logic, means, or instructions, or any combination thereof for concurrently forming a plurality of voids between the first selection region and the second selection region and forming a plurality of cavities through the first selection region and the second selection region, the plurality of voids having the first width and extending to a sacrificial material formed over a second void between the first block of memory cells and the second block of memory cells, and the plurality of cavities having a third width and extending to a plurality of strings of memory cells associated with the first block and the second block; forming a semiconductor material in the plurality of cavities, where the respective transistors are operable based at least in part on the semiconductor material; and forming the first portions of the first dielectric material based at least in part on forming the first dielectric material in the plurality of voids.

Aspect 7: The method or apparatus of any of aspects 1 through 6, where forming the electrical isolation region includes operations, features, circuitry, logic, means, or instructions, or any combination thereof for forming one or more voids having the second width, each of the one or more voids extending between the first portions of the first dielectric material and forming the second portions of the second dielectric material based at least in part on forming the second dielectric material in the one or more voids.

Aspect 8: The method or apparatus of any of aspects 1 through 7, further including operations, features, circuitry, logic, means, or instructions, or any combination thereof for forming one or more second electrical isolation regions through the first selection region, the one or more second electrical isolation regions including the second dielectric material and forming one or more third electrical isolation regions through the second selection region, the one or more third electrical isolation regions including the second dielectric material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: A memory device, including: a first array region of a memory die including a first block of memory cells and a first selection region over the first block of memory cells, where the first selection region includes a plurality of first transistors operable to couple memory cells of the first block with a plurality of first access lines; a second array region of the memory die including a second block of memory cells and a second selection region over the second block of memory cells, where the second selection region includes a plurality of second transistors operable to couple memory cells of the second block with a plurality of second access lines; and an electrical isolation region positioned between the first array region and the second array region, the electrical isolation region including first portions of a first dielectric material having a first width between the first selection region and the second selection region, and second portions of a second dielectric material having a second width between the first selection region and the second selection region.

Aspect 10: The memory device of aspect 9, where: each of the plurality of first transistors is operable to couple a respective first string of memory cells of the first block with a respective first access line of the plurality of first access lines; and each of the plurality of second transistors is operable to couple a respective second string of memory cells of the second block with a respective second access line of the plurality of second access lines.

Aspect 11: The memory device of aspect 10, where each of the first strings of memory cells and each of the second strings of memory cells includes: a respective semiconductor channel along the string, the respective semiconductor channel including a plurality of channel portions each associated with a respective memory cell along the string.

Aspect 12: The memory device of aspect 11, where: each of the channel portions is coupled with a respective portion of a storage material of the associated memory cell; and each of the plurality of first transistors and each of the plurality of second transistors does not include the storage material.

Aspect 13: The memory device of any of aspects 9 through 12, where the electrical isolation region includes the first dielectric material positioned between the first block of memory cells and the second block of memory cells.

Aspect 14: The memory device of aspect 13, where: the first array region includes a plurality of first word lines associated with the first block of memory cells; the second array region includes a plurality of second word lines associated with the second block of memory cells; and the plurality of first word lines are isolated from the plurality of second word lines based at least in part on the first dielectric material positioned between the first block of memory cells and the second block of memory cells.

Aspect 15: The memory device of any of aspects 9 through 14, where: the plurality of first access lines are over the first selection region and the plurality of second access lines are over the second selection region; the plurality of first transistors are operable to couple the memory cells of the first block with the plurality of first access lines based at least in part on one or more first activation lines of the first selection region; and the plurality of second transistors are operable to couple the memory cells of the second block with the plurality of second access lines based at least in part on one or more second activation lines of the second selection region.

Aspect 16: The memory device of aspect 15, further including: one or more second electrical isolation regions through the first selection region, the one or more second electrical isolation regions separating subsets of one or more of the first activation lines based at least in part on the second dielectric material; and one or more third electrical isolation regions through the second selection region, the one or more third electrical isolation regions separating subsets of one or more of the second activation lines based at least in part on the second dielectric material.

Aspect 17: The memory device of any of aspects 9 through 16, where the second dielectric material is a same dielectric material as the first dielectric material, and the first portions and the second portions of the same dielectric material are distinguishable by discontinuities between the first portions and the second portions.

Aspect 18: The memory device of any of aspects 9 through 17, where the second dielectric material is a different material than the first dielectric material.

Aspect 19: The memory device of any of aspects 9 through 18, where the first width of the first portions is wider than the second width of the second portions.

An apparatus is described. The following provides an overview of aspects of the apparatus as described herein:

Aspect 20: A memory device formed by a process including: forming a first block of memory cells and a second block of memory cells over a substrate; forming a first selection region over the first block of memory cells and a second selection region over the second block of memory cells, the first selection region and the second selection region including respective transistors operable to couple memory cells of the first block and the second block with a plurality of access lines; and forming an electrical isolation region between the first selection region and the second selection region, the electrical isolation region including first portions of a first dielectric material having a first width between the first selection region and the second selection region, and the electrical isolation region including second portions of a second dielectric material having a second width between the first selection region and the second selection region.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a first array region of a memory die comprising a first block of memory cells and a first selection region over the first block of memory cells, wherein the first selection region comprises a plurality of first transistors operable to couple memory cells of the first block with a plurality of first access lines;
a second array region of the memory die comprising a second block of memory cells and a second selection region over the second block of memory cells, wherein the second selection region comprises a plurality of second transistors operable to couple memory cells of the second block with a plurality of second access lines; and
an electrical isolation region positioned between the first array region and the second array region, the electrical isolation region comprising first portions of a first dielectric material having a first width between the first selection region and the second selection region, and second portions of a second dielectric material having a second width between the first selection region and the second selection region.

2. The memory device of claim 1, wherein:
each of the plurality of first transistors is operable to couple a respective first string of memory cells of the first block with a respective first access line of the plurality of first access lines; and
each of the plurality of second transistors is operable to couple a respective second string of memory cells of the second block with a respective second access line of the plurality of second access lines.

3. The memory device of claim 2, wherein each of the first strings of memory cells and each of the second strings of memory cells comprises:
a respective semiconductor channel along the string, the respective semiconductor channel comprising a plurality of channel portions each associated with a respective memory cell along the string.

4. The memory device of claim 3, wherein:
each of the channel portions is coupled with a respective portion of a storage material of the associated memory cell; and
each of the plurality of first transistors and each of the plurality of second transistors does not include the storage material.

5. The memory device of claim 1, wherein the electrical isolation region comprises the first dielectric material positioned between the first block of memory cells and the second block of memory cells.

6. The memory device of claim 5, wherein:
the first array region comprises a plurality of first word lines associated with the first block of memory cells;
the second array region comprises a plurality of second word lines associated with the second block of memory cells; and
the plurality of first word lines are isolated from the plurality of second word lines based at least in part on the first dielectric material positioned between the first block of memory cells and the second block of memory cells.

7. The memory device of claim 1, wherein:
the plurality of first access lines are over the first selection region and the plurality of second access lines are over the second selection region;
the plurality of first transistors are operable to couple the memory cells of the first block with the plurality of first access lines based at least in part on one or more first activation lines of the first selection region; and
the plurality of second transistors are operable to couple the memory cells of the second block with the plurality of second access lines based at least in part on one or more second activation lines of the second selection region.

8. The memory device of claim 7, further comprising:
one or more second electrical isolation regions through the first selection region, the one or more second electrical isolation regions separating subsets of one or more of the first activation lines based at least in part on the second dielectric material; and
one or more third electrical isolation regions through the second selection region, the one or more third electrical isolation regions separating subsets of one or more of the second activation lines based at least in part on the second dielectric material.

9. The memory device of claim 1, wherein the second dielectric material is a same dielectric material as the first dielectric material, and the first portions and the second portions of the same dielectric material are distinguishable by discontinuities between the first portions and the second portions.

10. The memory device of claim 1, wherein the second dielectric material is a different material than the first dielectric material.

11. The memory device of claim 1, wherein the first width of the first portions is wider than the second width of the second portions.

12. A method, comprising:
forming a first block of memory cells and a second block of memory cells over a substrate;
forming a first selection region over the first block of memory cells and a second selection region over the second block of memory cells, the first selection region and the second selection region comprising respective transistors operable to couple memory cells of the first block and the second block with a plurality of access lines; and
forming an electrical isolation region between the first selection region and the second selection region, the electrical isolation region comprising first portions of a first dielectric material having a first width between the first selection region and the second selection region, and the electrical isolation region comprising second portions of a second dielectric material having a second width between the first selection region and the second selection region.

13. The method of claim 12, wherein forming the first block of memory cells and the second block of memory cells comprises:
forming, prior to forming the first selection region and the second selection region, a plurality of cavities through a stack of material layers associated with the first block of memory cells and the second block of memory cells, the stack of material layers comprising alternating layers of an oxide material and a nitride material; and
forming a plurality of strings of memory cells based at least in part on forming a semiconductor material and a storage material in a plurality of first cavities of the plurality of cavities.

14. The method of claim 13, further comprising:
forming a void between the first block of memory cells and the second block of memory cells based at least in part on removing a first sacrificial material from one or more second cavities of the plurality of cavities, wherein forming the electrical isolation region is based at least in part on forming the void; and
forming a second sacrificial material over the void and over a top layer of the stack of material layers on opposite sides of the void.

15. The method of claim 12, further comprising:
forming a plurality of first cavities through a stack of material layers of the first selection region and the second selection region, the stack of material layers comprising alternating layers of an oxide material and a nitride material, the plurality of first cavities having the first width and extending to a sacrificial material formed over a second void between the first block of memory cells and the second block of memory cells, and the stack of material layers including continuous portions from the first selection region to the second selection region between the plurality of first cavities; and
forming the first portions of the first dielectric material based at least in part on forming the first dielectric material in the plurality of first cavities.

16. The method of claim 12, further comprising:
replacing, prior to forming the electrical isolation region, a plurality of layers of a nitride material of the first block of memory cells, the second block of memory cells, the first selection region, and the second selection region with a conductive material while one or more oxide layers extend from the first selection region to the second selection region over one or more voids between the first block of memory cells and the second block of memory cells, wherein the respective transistors are operable based at least in part on replacing the nitride material with the conductive material.

17. The method of claim 12, further comprising:
concurrently forming a plurality of voids between the first selection region and the second selection region and forming a plurality of cavities through the first selection region and the second selection region, the plurality of voids having the first width and extending to a sacrificial material formed over a second void between the first block of memory cells and the second block of memory cells, and the plurality of cavities having a third width and extending to a plurality of strings of memory cells associated with the first block and the second block;
forming a semiconductor material in the plurality of cavities, wherein the respective transistors are operable based at least in part on the semiconductor material; and
forming the first portions of the first dielectric material based at least in part on forming the first dielectric material in the plurality of voids.

18. The method of claim 12, wherein forming the electrical isolation region comprises:
forming one or more voids having the second width, each of the one or more voids extending between the first portions of the first dielectric material; and
forming the second portions of the second dielectric material based at least in part on forming the second dielectric material in the one or more voids.

19. The method of claim 12, further comprising:
forming one or more second electrical isolation regions through the first selection region, the one or more second electrical isolation regions comprising the second dielectric material; and
forming one or more third electrical isolation regions through the second selection region, the one or more third electrical isolation regions comprising the second dielectric material.

20. A memory device formed by a process comprising:
forming a first block of memory cells and a second block of memory cells over a substrate;
forming a first selection region over the first block of memory cells and a second selection region over the second block of memory cells, the first selection region and the second selection region comprising respective transistors operable to couple memory cells of the first block and the second block with a plurality of access lines; and
forming an electrical isolation region between the first selection region and the second selection region, the electrical isolation region comprising first portions of a first dielectric material having a first width between the first selection region and the second selection region, and the electrical isolation region comprising second portions of a second dielectric material having a second width between the first selection region and the second selection region.
